(19) United States
(12) Patent Application Publication
(10) Pub. No.: US 2018/0339936 A1
(43) Pub. Date: Nov. 29, 2018

(54) MANUFACTURING METHOD OF GLASS SUBSTRATE AND GLASS SUBSTRATE

(71) Applicant: Asahi Glass Company, Limited, Chiyoda-ku (JP)

(72) Inventors: Motoshi Ono, Chiyoda-ku (JP); Mamoru Isobe, Chiyoda-ku (JP); Shigetoshi Mori, Chiyoda-ku (JP); Kohei Horiuchi, Chiyoda-ku (JP)

(73) Assignee: Asahi Glass Company, Limited, Chiyoda-ku (JP)

(21) Appl. No.: 15/989,934

(22) Filed: May 25, 2018

(30) Foreign Application Priority Data
May 29, 2017 (JP) 2017-106007

(51) Int. Cl. C03C 15/00; H05K 3/00; C03C 23/00; B23K 26/00; B23K 26/382

(52) U.S. Cl. CPC C03C 15/00; H05K 3/0029; H05K 3/002; C03C 23/0025; H05K 1/115; B23K 26/382; H05K 2203/0285; H05K 2203/107; B23K 26/0006

(57) ABSTRACT

A manufacturing method of a glass substrate having through holes includes
(i) irradiating at a through hole forming target position on a first surface of the glass substrate with a laser light; and
(ii) performing a wet etching treatment on the glass substrate.

During the wet etching treatment being performed on the glass substrate, an ultrasonic vibration with a frequency of less than 40 kHz is applied to an etchant over at least a part of the wet etching period, referred to as an ultrasonic vibration application period.

### CROSS-REFERENCE TO RELATED APPLICATION

The present application is based on and claims benefit of priority under 35 U.S.C. § 119 of Japanese Patent Application No. 2017-106007, filed May 29, 2017. The contents of the application are incorporated herein by reference in their entirety.

### BACKGROUND OF THE INVENTION

### 1. Field of the Invention

The disclosure herein generally relates to a manufacturing method of a glass substrate and a glass substrate, particularly relates to a glass substrate having a through hole and a manufacturing method thereof.

### 2. Description of the Related Art

Conventionally, a glass substrate having fine through holes has been widely used. For example, a glass substrate having a plurality of fine through holes, in which a conductive material is filled, has been used as a glass interposer.

### SUMMARY OF THE INVENTION

Typically, a glass substrate having through holes is formed by irradiating at a through hole forming target position on a surface of the glass substrate with laser, to form initial through holes, and performing a wet etching treatment on the glass substrate. The initial through holes were expanded according to the wet etching treatment, and thereby through holes having desired shapes can be formed.

Recently, finer through holes, i.e. through holes with smaller diameters, have been required. In order to satisfy the requirement, diameters of the initial through holes before performing wet etching treatment needs to be further smaller, and, as a result, diameters of apertures at both ends of each through hole need to be smaller.

However, when the diameters of the apertures of the initial through holes become smaller, when performing the wet etching treatment, it becomes difficult for an etchant to sufficiently penetrate inside the initial through holes. As a result, inside the through holes obtained after the etching, a part with small diameter (referred to as a “constriction part”) may be generated.

Such a constriction part may create an adverse effect when a conductive material is filled in the through holes after the etching treatment. That is, when a constriction part is present in a through hole, it may become difficult to uniformly fill the conductive material inside the through hole.

Moreover, even if the conductive material can be filled in the through holes, when a constriction part of a conductive material is present in a glass substrate having through electrodes (e.g. a glass interposer), an electric resistance of the constriction part, in which the conductive material is filled, increases, and an electric characteristic required for the glass substrate having through electrodes may not be obtained.

Note that U.S. Pat. No. 9,296,646 discloses applying ultrasonic vibrations to a glass substrate when performing a wet etching treatment. U.S. Pat. No. 9,296,646 describes that in this case, an etchant sufficiently penetrates inside initial through holes, and a constriction part can be controlled in a through hole obtained after the etching treatment.

However, the inventors of the present application have experimentally found that even if such a countermeasure is applied, constriction parts are not sufficiently controlled.

The present invention was made in view of the aforementioned problem, and aims at providing a manufacturing method of a glass substrate having through holes in which constriction parts are significantly controlled. Moreover, the present invention aims at providing a glass substrate having through holes in which constriction parts are significantly controlled.

### Solution to Problem

An aspect of the present invention provides

a manufacturing method of a glass substrate having through holes, comprising

(i) irradiating at a through hole forming target position on a first surface of the glass substrate with a laser light; and

(ii) performing a wet etching treatment on the glass substrate.

In the step (ii), the glass substrate is subjected to the wet etching treatment in a state where an ultrasonic vibration with a frequency of less than 40 kHz is applied to an etchant over at least a part of a wet etching period referred to as an ultrasonic vibration application period.

Moreover, an aspect of the present invention provides a glass substrate including a first surface; a second surface and a through hole that penetrates from the first surface to the second surface.

The through hole has a first aperture with a first diameter ϕ₁ on the first surface and a second aperture with a second diameter ϕ₂ on the second surface, the first diameter ϕ₁ being larger than or equal to the second diameter ϕ₂.

The through hole has a constriction part inside the glass substrate, the constriction part has a third diameter ϕ₃ in a cross-section orthogonal to an extending direction of the through hole, the third diameter ϕ₃ being less than the second diameter ϕ₂.

An aspect ratio of a thickness of the glass substrate (t) to the first diameter (ϕ₁), t/ϕ₁, is 25 or less, and a ratio of the third diameter (ϕ₃) to the first diameter (ϕ₁), ϕ₃/ϕ₁, is 0.50 or more.

Both an arithmetic average roughness Ra of the first surface near the first aperture and arithmetic average surface roughness Ra of the second surface near the second aperture are 0.05 μm or less.

### Effect of Invention

According to an aspect of the present invention, a manufacturing method of a glass substrate having through holes in which constriction parts are significantly reduced can be provided. Moreover, according to an aspect of the present invention, a glass substrate having through holes in which constriction parts are significantly reduced can be provided.

### BRIEF DESCRIPTION OF THE DRAWINGS

Other objects, features and advantages of the present invention will become more apparent from the following detailed description when read in conjunction with the accompanying drawings, in which:

FIG. 1 is a perspective view schematically depicting an example of a glass substrate according to an embodiment;

FIG. 2 is a diagram schematically depicting an example of a mode of a cross section of a through hole formed on the glass substrate illustrated in FIG. 1;

FIG. 3 is a flowchart schematically depicting an example of a flow of a manufacturing method of a glass substrate according to the embodiment;

FIG. 4 is a perspective view schematically depicting an example of a mode of the glass substrate to be processed;

FIG. 5 is a perspective view schematically depicting an example of a glass substrate in which a plurality of initial through holes are formed;

FIG. 6 is a cross-sectional view schematically depicting an example of a mode of a cross section of an initial through hole formed on the glass substrate illustrated in FIG. 5;

FIG. 7 is a diagram schematically depicting a shape of a through hole obtained by performing the wet etching treatment to an initial through hole using the conventional method;

FIG. 8 is a timing chart for performing the wet etching treatment to the glass substrate;

FIG. 9 is a cross-sectional view schematically depicting a shape of the through hole obtained after the wet etching treatment in the manufacturing method of the glass substrate according to the embodiment;

FIG. 10 is a flowchart schematically depicting another example of the flow of the manufacturing method of the glass substrate according to the embodiment;

FIG. 11 is a photograph depicting an example of a cross section of the initial through hole obtained after the laser irradiation in the first example;

FIG. 12 is a photograph depicting an example of a cross section of the through hole obtained after the wet etching treatment in the first example;

FIG. 13 is a photograph depicting an example of a cross section of the through hole obtained after the wet etching treatment in the second example;

FIG. 14 is a photograph depicting an example of a cross section of the through hole obtained after the wet etching treatment in the third example; and

FIG. 15 is a photograph depicting an example of a cross section of the through hole obtained after the wet etching treatment in the fourth example.

### DETAILED DESCRIPTION OF THE PREFERRED EMBODIMENTS

In the following, with reference to drawings, embodiments of the present invention will be described.

(Glass Substrate According to Embodiment)

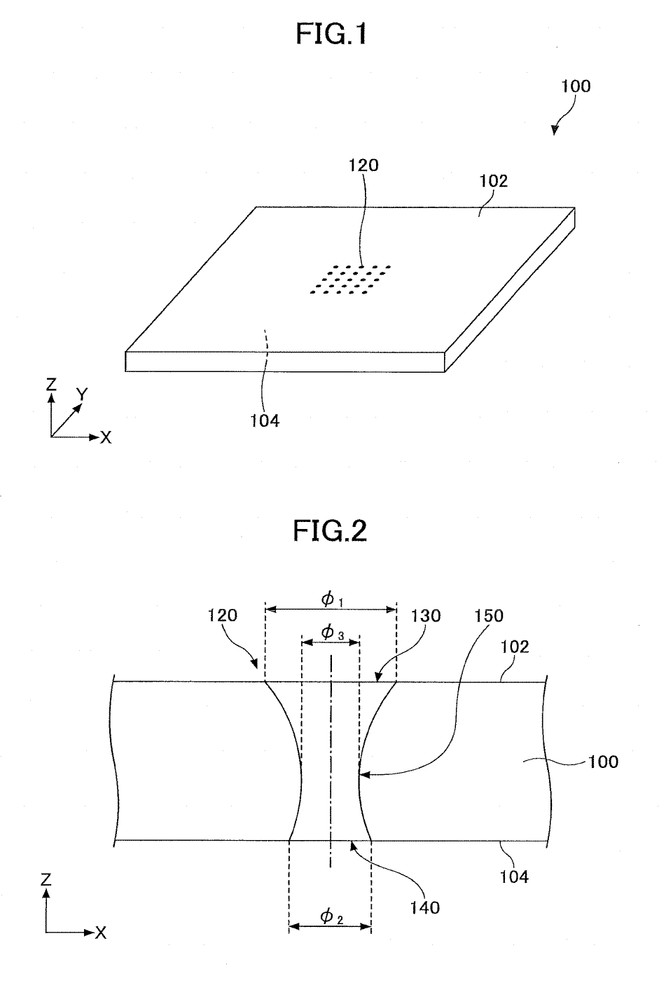

FIG. 1 is a perspective view schematically depicting an example of a glass substrate according to an embodiment (in the following, referred to as a “first glass substrate”).

As illustrated in FIG. 1, the first glass substrate 100 has a first surface 102 and a second surface 104 that are opposite to each other, and has a substantially rectangular shape. However, the shape of the first glass substrate 100 is not particularly limited. For example, the shape of the first glass substrate 100 may be any shape such as a circle or an ellipse.

Moreover, the glass substrate 100 may be a glass plate of any composition. For example, the glass substrate 100 may be a soda-lime glass, an alkali-free glass, or a quartz glass.

As illustrated in FIG. 1, the first glass substrate 100 has a through hole 120 or two or more through holes 120 that extend from the first surface 102 to the second surface 104. Note that in the example illustrated in FIG. 1, the plurality of through holes 120 are arranged around a center of the first surface 102. However, this is merely an example, and the position of forming the through holes 120 is not particularly limited. Moreover, the through holes 120 may be arranged uniformly (at regular intervals) on the first surface 102, or may be arranged irregularly (different intervals and/or different patterns).

FIG. 2 is a diagram schematically depicting an example of a mode of a cross section of the through hole 120. FIG. 2 illustrates the mode of the cross section of the through hole 120 cut along an axis of expansion (central axis).

As illustrated in FIG. 2, the through hole 120 has a first aperture 130 formed on the first surface 102 of the glass substrate 100 and a second aperture 140 formed on the second surface 104. The first aperture 130 has a diameter ϕ₁, and the second aperture 140 has a diameter ϕ₂.

In the present application ϕ₁, is assumed to be larger than or equal to ϕ₂. That is, a surface having a larger diameter of an aperture of the through hole 120 will be referred to as a first surface 102, and a surface having a smaller diameter of an aperture of the through hole 120 will be referred to as a second surface 104. Note that in the case where both the diameters of the apertures ϕ₁ and ϕ₂ are substantially the same, either of the surfaces may be referred to as the first surface 102. The diameters (ϕ₁ and ϕ₂) may be obtained by specifying three points on an edge of an aperture to be measured (first aperture 130 and the second aperture 104) by using a reflection type optical microscope (e.g. Asahikogaku MS-200), and calculating from an approximate circle for the three points. Three points may be positions of 12 o'clock, 4 o'clock, and 8 o'clock of the edges of the aperture. When a plurality of through holes 120 are present, 10 through holes may be selected, of which their respective diameters may be obtained, and an average value of the diameters may be obtained.

Moreover, the through hole 120 has a constriction part 150 inside the through hole. The constriction part 150 is defined as a part having the smallest diameter in a cross section orthogonal to the axis of expansion of the through hole 120. Thus, a diameter ϕ₃ of the constriction part 150 is less than or equal to ϕ₂. The diameter ϕ₃ of the constriction part is measured as follows. When the through hole 120 is irradiated with a transmitted illumination from the second surface 104 of the glass substrate side, a smallest outline of the through hole, observed using a length measuring device or the like, is approximated as a circle by a least-squares method. A diameter of the approximated circle is defined as the diameter ϕ₃ of the constriction part of the through hole. When a plurality of through holes 120 are present, 10 through holes may be selected, of which their respective diameters ϕ₃ may be obtained, and an average value of the diameters may be obtained.

Note that in the example of the cross section, illustrated in FIG. 2, a side wall of the through hole 120 has a curved shape. However, this is merely an example, and the side wall of the through hole 120 may have a shape substantially formed of a plurality of straight lines. Alternatively, the side wall of the through hole 120 may have a shape formed of one line or two or more lines and one curve or two or more curves.

Here the first glass substrate 100 has a feature that an aspect ratio t/ϕ₁ of the first glass substrate 100 is 25 or less and a ratio ϕ₃/ϕ₂ is 0.50 or more. Note that t represents a thickness of the first glass substrate 100.

Moreover, the first glass substrate 100 has a feature that a surface roughness (arithmetic average roughness Ra) of the first surface 102 near the first aperture 130 and of the second surface 104 near the second aperture 140 is 0.05 μm or less.

Here, “near aperture” means an area between an outer periphery part of the aperture and a line separated from the outer periphery by 5 mm in a radial direction. For calculation, the surface roughness (arithmetic average roughness Ra) can be obtained by measuring using a confocal laser scanning microscope (e.g. confocal laser scanning microscope VK-X series by Keyence Corporation), and a surface irregularity in the area is measured at a measured length of 100 μm.

In this way, in the first substrate 100, the diameter ϕ₃ of the constriction part 150 of the through hole 120 is sufficiently large. In other words, the through hole 120 does not have a noticeable constriction part 150.

Thus, in the first glass substrate 100, a conductive material can be filled inside the through hole 120 relatively easily. Moreover, in the first glass substrate 100, a possibility that an electric resistance of the filled part of the constriction part of the through hole 120 increases, and that a desired electric characteristic may not be obtained in a glass substrate having through through electrodes (e.g. glass interposer) can be reduced significantly.

The glass substrate 100 having such features can be applied to a high frequency device, for example.

(Manufacturing Method of Glass Substrate According to the Embodiment)

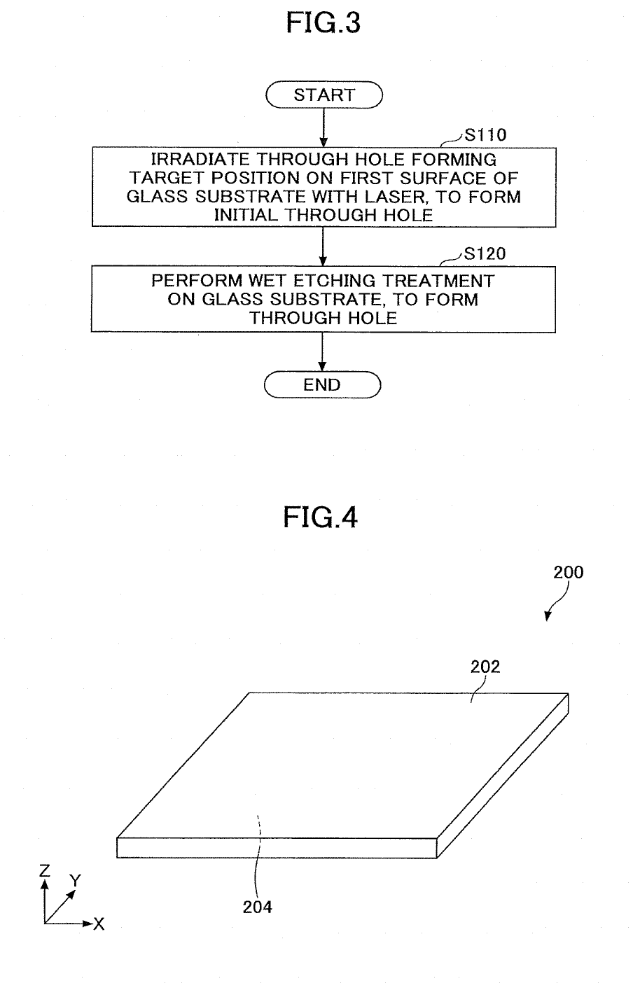

Next, with reference to FIG. 3, an example of a manufacturing method of a glass substrate according to the embodiment will be described.

FIG. 3 is a flowchart schematically depicting a flow of the manufacturing method of the glass substrate according to the embodiment (in the following, referred to as a “first manufacturing method”).

As illustrated in FIG. 3, the first manufacturing method includes:

(i) a step of irradiating at a through hole forming target position of a first surface of a glass substrate with a laser, to form an initial through hole (step S110); and

(ii) a step of performing a wet etching on the glass substrate, to form a through hole (step S120).

In the following, each step will be described in detail.

(Step S110)

First, a glass substrate to be processed is provided.

FIG. 4 schematically depicts an example of the glass substrate.

A glass substrate 200 has a first surface 202 and a second surface 204.

The glass substrate 200 may be a glass plate of any composition. For example, the glass substrate 200 may be a soda-lime glass, an alkali-free glass, or a quartz glass.

A thickness of the glass substrate 200 is not particularly limited, but falls within a range from 0.05 mm to 0.7 mm, for example.

Note that a shape of the glass substrate 200 is not limited to a rectangular shape illustrated in FIG. 4, but may be any shape such as a circle or a ellipse.

Next, the through hole forming target position of the first surface 202 of the glass substrate 200 is irradiated with laser.

A type of laser is not particularly limited, but the laser may be a pulsed laser with a pulse width of 100 nsec or less. The laser may be a YVO₄ laser, for example.

By the laser irradiation, an initial through hole that penetrates from the through hole forming target position on the first surface 202 to the second surface 204 is formed.

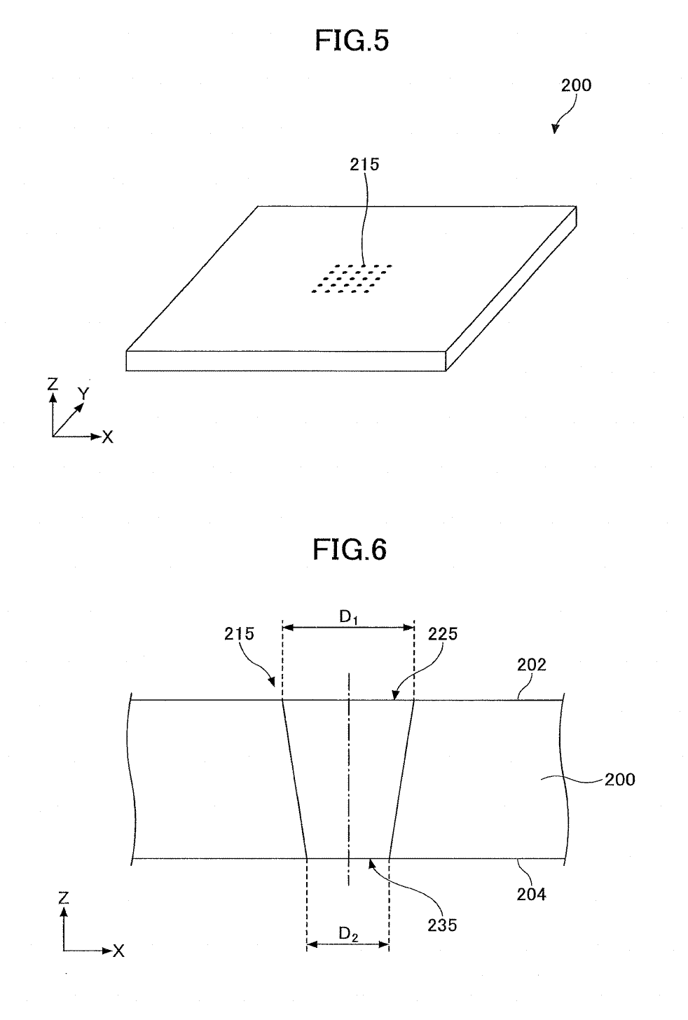

FIG. 5 is a perspective view depicting the glass substrate 200 in which a plurality of initial through holes 215 are formed. FIG. 6 is a cross-sectional view schematically depicting a mode of a cross section of the initial through hole 215 cut along the axis of expansion.

As illustrated in FIG. 6, the initial through hole 215 has a first aperture 225 on the first surface 202, and a second aperture 235 on the second surface 204. Note that in a typical case, an initial through hole 215 has a tapered shape in which a diameter decreases toward the second surface 204 from the first surface 202. That is, in the initial through hole 215, a diameter D₁ of the first aperture 225 is larger than or equal to a diameter D₂ of the second aperture 235.

The diameter D₁ of the first aperture 225 is, for example, 20 μm or less, and may be 18 μm or less. As the diameter D₁ of the first aperture 225 becomes smaller, a constriction part becomes more likely to be formed after wet etching. The embodiment of the present invention achieves a remarkable effect as the first aperture 225 becomes smaller.

(Step S120)

Next the glass substrate 200 having the initial through hole 215 is subjected to the wet etching treatment. This treatment is performed in order to extend the diameter of the initial through hole 215 to a predetermined dimension.

An etchant (hereinafter referred to as an etchant) is not particularly limited, but typically an aqueous solution including a hydrofluoric acid is used. A concentration of hydrofluoric acid is not particularly limited and determined based on a required etching speed.

An etching speed falls, for example, within a range from 0.05 μm/min to 2.0 μm/min. The etching speed may fall within a range from 0.1 μm/min to 1.0 μm/min, and is preferably 0.3 μm/min or less.

In the case where the glass substrate 200 is merely subjected to wet etching treatment, a through hole having a constriction part may be formed.

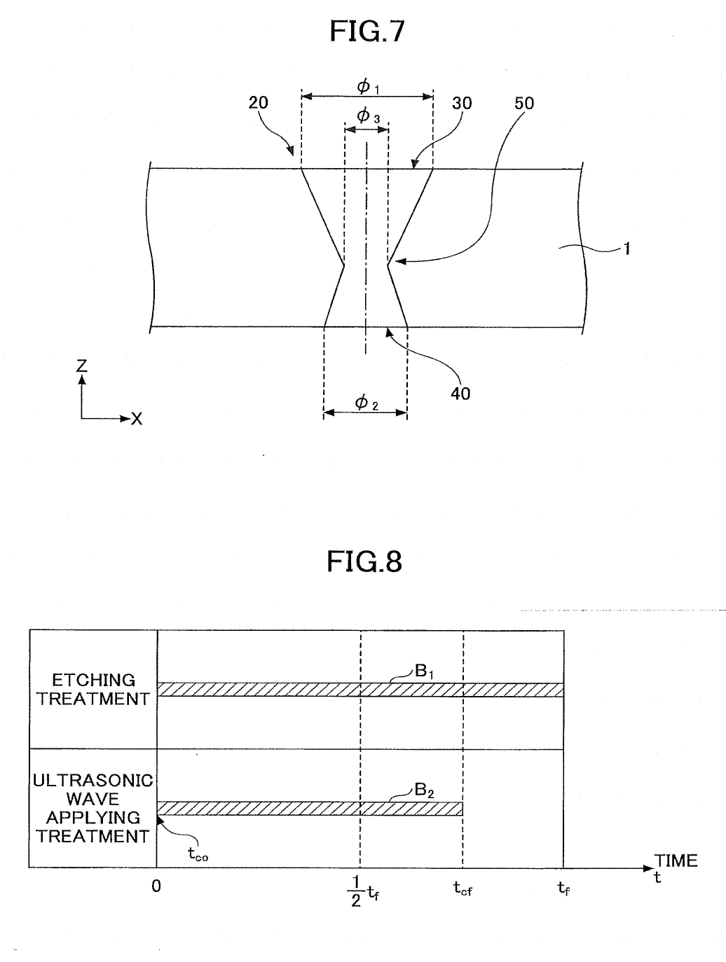

FIG. 7 schematically illustrates a shape of the through hole.

As illustrated in FIG. 7, the through hole 20 penetrates the glass substrate 1, and has a first aperture 30 and a second aperture 40. Moreover, the through hole 20 has a constriction part 50 at about a center of the thorough hole in a thickness direction of the glass substrate 1.

A diameter ϕ₁ of the first aperture 30 is larger than a diameter of ϕ₂ of the second aperture 40, and the diameter ϕ₂ of the second aperture is larger than a diameter ϕ₃ of the construction part 50.

Such a through hole 20 having a constriction part 50 is considered to be formed because an etchant cannot sufficiently enter an inside of the through hole 20 when the wet etching treatment is performed or because a circulation of the etchant inside the through hole 20 is insufficient. That is, the etchant inside the through hole 20 is insufficient or degrades compared with the apertures 30, 40 and near the apertures. It is expected that the constriction part 50 is formed inside the through hole 20 as a result.

Particularly, in the initial through hole 215, illustrated in FIG. 6, when the diameter D₁ of the first aperture 225 and the diameter D₂ of the second aperture 235 become smaller, an etchant is prevented from entering the through hole 20 or from circulating inside the through hole 20, and the constriction part 50 is likely to be formed. Moreover, as a ratio t/D₁ increases, the constriction part 50 is more likely to be formed. For example, when the diameter D₁ is 20 μm or less and/or the ratio t/D₁ is 10 or more, a conspicuous constriction part is like to be formed.

When such a constriction part 50 is formed inside the through hole 20, it may become difficult to uniformly fill a conductive material inside the through hole 20. Moreover, when a conductive material is filled inside such a through hole 20, an electric resistance of a part where the conductive material is filled in the constriction part increases, and a desired electric characteristic of the glass substrate having through electrodes may not be obtained.

In contrast, in the first manufacturing method, the wet etching treatment is performed over at least a part of the entire period, in a state where an ultrasonic vibration with a frequency of less than 40 kHz is applied to the etchant. Note that, in the following, a process of applying an ultrasonic vibration to the etchant will be referred to as an “ultrasonic vibration application treatment”.

In the case of performing such an ultrasonic vibrations application treatment during the wet etching treatment, it becomes possible to cause the etchant to sufficiently enter the initial through hole 215 and to circulate inside the through hole 215. Thus, in the first manufacturing method, a conspicuous constriction part can be significantly prevented from occurring inside the through hole obtained after the etching treatment.

Note that in the ultrasonic vibration application treatment, an ultrasonic vibration with a frequency of less than 40 kHz is applied to the etchant. As a result, a great vibration energy is given to the glass substrate 200 to be subjected to the etching treatment, and there could be concern for damage to the glass substrate.

However, the inventors of the present application have confirmed experimentally that any damage such as a roughness, breakage and/or a crack on a surface did not occur in the glass substrate for which the “ultrasonic vibration application treatment” had been performed.

Thus, in the first manufacturing method, it is possible to significantly prevent a conspicuous constriction part from occurring in a through hole while preventing damages from occurring in the glass substrate 200.

In the following, with reference to FIG. 8, the ultrasonic vibration application treatment will be described in detail.

FIG. 8 schematically depicts a timing chart in the step S120 in the first manufacturing method. FIG. 8 illustrates both a period of performing the wet etching treatment for the glass substrate and a period of performing the ultrasonic vibration application treatment.

As illustrated in FIG. 8, a line segment indicating a period of performing the wet etching for the glass substrate (in the following, referred to as an “etching treatment period”) B₁ extends on a time axis (horizontal axis) from a start point 0 (zero) to an end point t_{f}. In other words, the wet etching treatment is performed from a time 0 to a time t_{f} (t_{f} is not zero). An etching treatment period B₁ indicates a period from the time 0 to the time t_{f}.

In contrast, a line segment indicating a period of the ultrasonic vibration application treatment (in the following, referred to as an “ultrasonic vibration application period”) B₂ extends on the time axis (horizontal axis) from the start point t_{c0} to an end point t_{cf}. In other words, the ultrasonic vibration application treatment is performed from a start time t_{c0} to a completion time t_{cf}. An ultrasonic vibration application treatment B₂ indicates a period from the start time t_{c0} to the completion time t_{cf}.

Here, in the example illustrated in FIG. 8, the ultrasonic vibration application period B₂ extends from the time 0 to a time that exceeds ½·t_{f}. That is, the time tc0 is zero, and the time t_{cf} is greater than ½·t_{cf}.

However, the above example is merely an example, and the ultrasonic vibration application period B₂ may be performed in any appropriate part of the etching treatment period B₁.

For example, the ultrasonic vibration application period B₂ may coincide with the etching treatment period B₁. In this case, the time t_{c0} is zero, and the time t_{cf} is t_{f}. Alternatively, the ultrasonic vibration application period B₂ may be a period from the time 0 to a time less than the time ½·t_{f}. In this case the time t_{c0} is zero and the time t_{cf} is less than ½·t_{f}. Moreover, the ultrasonic vibration application period B₂ may not necessarily start at the time 0. In this case, the start point t_{c0} is greater than the time zero.

However, typically, the start point t_{c0} of the ultrasonic vibration application period B₂ is preferably 0 (zero) or near 0. Moreover, the end point t_{cf} of the ultrasonic vibration application period B₂ preferably satisfies the relation t_{cf}>½·t_{f}, as illustrated in FIG. 8.

Note that in the ultrasonic vibration application treatment, an ultrasonic vibration with a frequency less than 40 kHz, preferably less than or equal to 35 kHz, more preferably less than or equal to 30 kHz is applied. Moreover, in the ultrasonic vibration application treatment, an ultrasonic vibration with a frequency greater than or equal to 20 kHz is applied.

Note that in the wet etching treatment, an oscillatory motion may be applied to the glass substrate 200. Particularly, in the ultrasonic vibration application treatment, an oscillatory motion is preferably applied to the glass substrate 200.

In this case, an etchant can be penetrated inside the initial through holes 215 more rapidly. Moreover, a product generated by the etching treatment can be discharged to the outside of the initial through hole 215 rapidly.

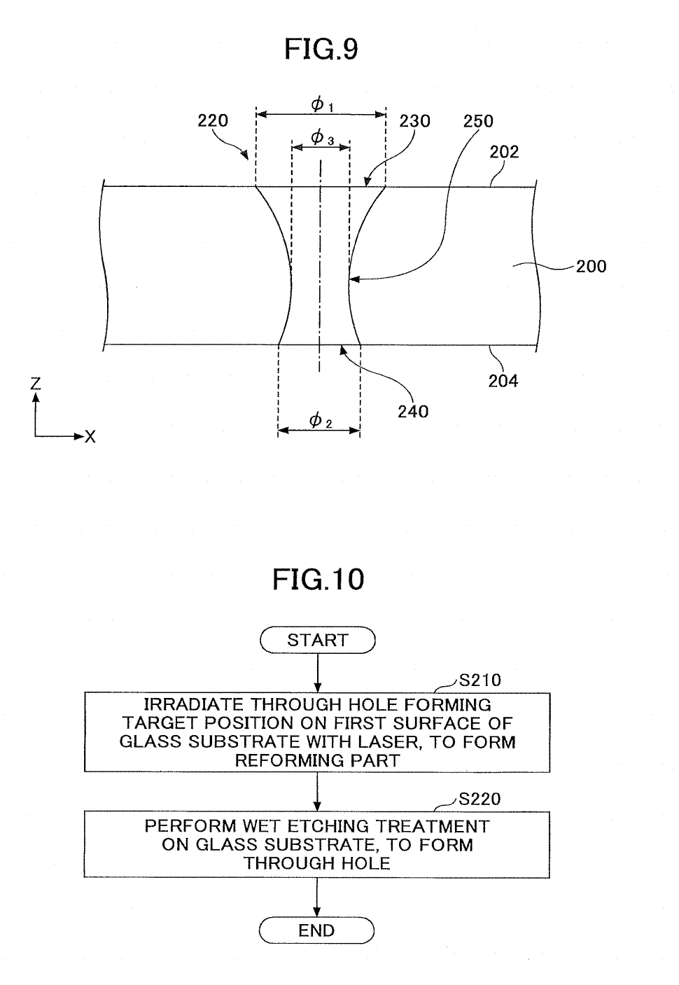

FIG. 9 is a cross-sectional view schematically depicting a shape of the through hole obtained after the wet etching treatment.

As illustrated in FIG. 9, the through hole 220 obtained after the wet etching treatment has a first aperture 230 on the first surface 202 of the glass substrate 200 and a second aperture 240 on the second surface 204. The first aperture 230 has a diameter ϕ₁ and the second aperture 240 has a diameter ϕ₂, which is less than or equal to ϕ₁.

Note that actually the first surface 202 of the glass substrate 200, illustrated in FIG. 6, is subjected to the wet etching treatment. Thus, the first surface of the glass substrate 200 illustrated in FIG. 9 is a newly generated surface by the wet etching treatment, and different from the first surface 202 of the glass substrate 200 illustrated in FIG. 6. However, here, in order to avoid a complicated description, the first surface of the glass substrate 200 illustrated in FIG. 9 is indicated by a reference numeral 202. The same applies to the second surface 204 of the glass substrate 200, illustrated in FIG. 9.

As illustrated in FIG. 9, the through hole 220 can have a constriction part 250 with a diameter ϕ₃ inside the through hole. However, a difference between the diameter ϕ₃ of the constriction part 250 and the diameter ϕ₁ or the diameter ϕ₂ is significantly reduced.

For example, in the through hole 220, a ratio ϕ₃/φ₁ is 0.50 or more. Moreover, an aspect ratio of the through hole 220, i.e. the thickness of the glass substrate 200 t divided by the diameter ϕ₁, is 25 or less.

In this way, in the first manufacturing method, it is possible to form the through hole 220 without a conspicuous constriction part after the wet etching treatment.

(Another Manufacturing Method of Glass Substrate According to the Embodiment)

Next, with reference to FIG. 10, an example of another manufacturing method of a glass substrate according to the embodiment of the present invention will be described.

FIG. 10 is a flowchart schematically depicting a flow of another manufacturing method of the glass substrate according to the embodiment (in the following, referred to as a “second manufacturing method”).

As illustrated in FIG. 10, the second manufacturing method includes:

(i) a step of irradiating at a through hole forming target position of a first surface of a glass substrate with a laser, to form a reforming part (step S210); and

(ii) a step of performing a wet etching on the glass substrate, to form a through hole (step S220).

In the following, each step will be described in detail.

(step S210)

First, a glass substrate to be processed is provided.

Note that a specification or the like of the glass substrate is the same as that of the aforementioned first manufacturing method. Thus, a detailed description of the glass substrate will be omitted here. Moreover, in the following, when indicating a glass substrate or the like, the reference numerals shown in FIG. 4 will be used.

Next, a through hole forming target position of the first first surface 202 of the glass substrate 200 is irradiated with a laser.

A type of laser is not particularly limited, but the laser may be a pulsed laser with a pulse width of 100 nsec or less. The laser may be a YVO₄ laser, for example.

By the laser irradiation, a laser reforming part that extends from the first surface 202 to the second surface 204 in the glass substrate is formed. Note that the laser reforming part is different from the initial through hole formed in the step S110 in the first manufacturing method, and at this stage does not have a shape of a “hole”.

However, because the shape of the laser reforming part in the glass substrate 200 is similar to the initial through hole 215, in the laser reforming part, a diameter on the first surface will be denoted as ϕ₁ and a diameter on the second surface will be denoted as ϕ₂.

(Step S220)

Next, the glass substrate 200 having the reforming part is subjected to the wet etching treatment. This treatment is performed in order to ablate the reforming part, and to form a through hole at the location of the reforming part

Also in the second manufacturing method, for at least a part of the entire period of performing the etching treatment, an ultrasonic vibration with a frequency of less than 40 kHz is applied to the etchant. Thus, also in the second manufacturing method, a conspicuous constriction part can be significantly prevented from occurring inside the through hole obtained after the etching treatment.

Note that substantially step S120 in the aforementioned first manufacturing method can be referred for step step S220. Therefore, further explanation will be omitted here.

After step S220, the glass substrate 220 having the through hole 220, illustrated in FIG. 9, can be obtained.

### EXAMPLE

Next, examples of the present invention will be described.

### Example 1

Using the aforementioned first manufacturing method, a glass substrate having a through hole was manufactured as follows.

First, a first surface of a glass substrate was irradiated with laser, and an initial through hole was formed. For the glass substrate, an alkali-free glass with a thickness of 0.5 mm was used. For a laser light, a third-harmonic of a YVO₄ laser (wavelength of 355 nm) was used.

A diameter ϕ₁ of a first aperture of the initial through hole obtained as above was 14.5 μm, and a diameter ϕ₂ of a second aperture was 3.1 μm.

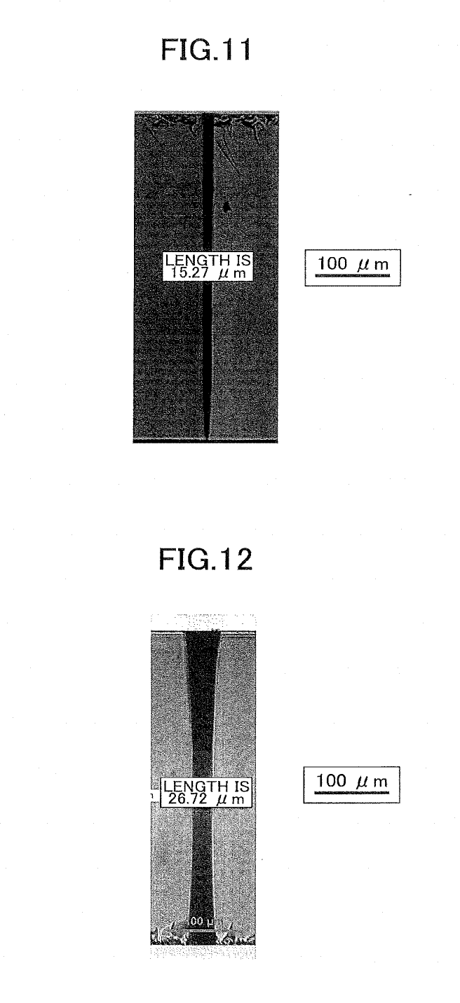

FIG. 11 depicts an example of a cross section of the initial through hole.

Next, the glass substrate was subjected to a wet etching treatment at a room temperature.

For an etchant, a mixed acid aqueous solution of hydrofluoric acid (0.5 vol %) and hydrochloric acid (1.0 vol %) was used. An etching period was 137 minutes.

Moreover, over an entire period for the wet etching treatment, ultrasonic vibrations were applied to the etchant. Thus, in the timing chart illustrated in FIG. 8, t_{c0} was 0 (zero) and t_{cf} was t_{f}.

The ultrasonic ultrasonic vibration was applied to the etchant by using an ultrasonic cleaning machine (VS-100III: by AS ONE Corporation). The frequency of the ultrasonic vibration was 28 kHz.

After the wet etching treatment, a glass substrate having through holes (referred to as a “sample 1”) was obtained. In the sample 1, a damage such as a crack was not found by visual inspection.

FIG. 12 depicts an example of a cross section of the through hole obtained as above.

### Example 2

A glass substrate having a through hole was manufactured as follows.

First, with the same method as Example 1, the first surface of the glass substrate was irradiated with laser, to form an initial through hole.

Next, the glass substrate was subjected to the wet etching treatment at room temperature. However, in Example 2, ultrasonic vibration was not applied to the etchant, and only the wet etching treatment was performed. For the etchant, the aforementioned mixed acid aqueous solution was used. An etching period was 195 minutes.

After the wet etching treatment, a glass substrate having through holes (referred to as a “sample 2”) was obtained.

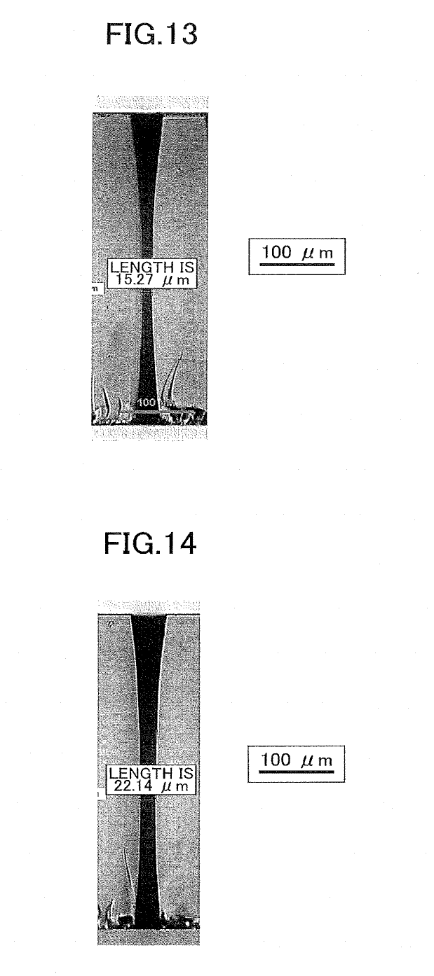

FIG. 13 depicts an example of a cross section of the through hole obtained as above.

### Example 3

A glass substrate having a through hole was manufactured with the same method as Example 1.

However, in Example 3, the frequency of the ultrasonic vibration applied to the etchant during the wet etching treatment was 45 kHz. Moreover, the etching period was 175 minutes.

After the wet etching treatment, a glass substrate having through holes (referred to as a “sample 3”) was obtained.

FIG. 14 depicts an example of a cross section of the through hole obtained as above.

### Example 4

A glass substrate having a through hole was manufactured with the same method as Example 1.

However, in Example 4, the frequency of the ultrasonic vibration applied to the etchant during the wet etching treatment was 100 kHz. Moreover, the etching period was 195 minutes.

After the wet etching treatment, a glass substrate having through holes (referred to as a “sample 4”) was obtained.

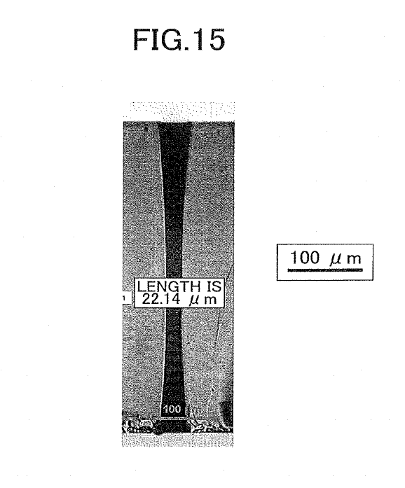

FIG. 15 depicts an example of a cross-section of the through hole obtained as above.

(Evaluation)

In each of the samples 1 to 4, surface roughnesses (arithmetic average roughness Ra) near the first aperture and the second aperture were measured. Moreover, dimensions of parts of the through hole were measured.

TABLE 1, in the following, shows results obtained for the respective samples as a whole.

TABLE 1

| | | frequency | surface | diameter | diameter | diameter of | | |
|---|---|---|---|---|---|---|---|---|
| | | of | roughness | of first | of second | constriction | | |
| | etching | ultrasonic | (Ra) of first | aperture | aperture | part | | aspect |
| | period | vibration | aperture | ϕ₁ | ϕ₂ | ϕ₃ | ratio | ratio |
| sample | (min) | (kHz) | (μm) | (μm) | (μm) | (μm) | ϕ₃/ϕ₁ | t/ϕ₁ |
| 1 | 137 | 28 | 0.036 | 45.0 | 36.5 | 26.1 | 0.58 | 10.4 |
| 2 | 195 | — | 0.033 | 45.0 | 35.0 | 14.9 | 0.33 | 10.4 |
| 3 | 175 | 45 | 0.040 | 46.6 | 36.3 | 21.9 | 0.47 | 10.1 |
| 4 | 195 | 100 | 0.033 | 46.5 | 36.8 | 20.9 | 0.45 | 10.1 |

Note that the surface roughness (arithmetic average roughness Ra) indicates only a result obtained near the first aperture. This is because the results obtained near the first aperture and near the second aperture were found to be almost the same.

From TABLE 1, it is found that a noticeable roughness on a surface of the glass substrate was not generated in any of the samples.

It is found that, in sample 2, in which the ultrasonic vibration was not applied and the wet etching treatment was performed, a conspicuous constriction part was generated, as shown in FIG. 13. The ratio ϕ₃/ϕ₁ was 0.33.

In contrast, it is found that, in sample 3, in which the wet etching treatment was performed in the state where the ultrasonic vibration was applied, the generation of the constriction part was somewhat controlled, compared with sample 2, as shown in FIG. 14. However, the ratio ϕ₃/ϕ₁ was 0.47, and a constriction part of considerable size was still formed. Similarly, in sample 4, the ratio ϕ₃/ϕ₁ is 0.45, and a constriction part of considerable size was still formed.

However, it is found that, in sample 1, the formation of the constriction part was significantly controlled, as shown in FIG. 12. The ratio ϕ₃/ϕ₁ is 0.58, and the constriction part was less conspicuous than the other samples.

In this way, it was confirmed that a formation of a constriction part could be significantly controlled by applying an ultrasonic vibration with a prescribed frequency when a wet etching treatment was performed.

As described above, the preferred embodiments and the like have been described in detail. However, the present invention is not limited to the above-described specific embodiments, and various variations and modifications may be made without deviating from the scope of the present invention.

### REFERENCE SIGNS LIST

1 glass substrate
20 through hole
30 first aperture
40 second aperture
50 constriction part
100 first glass substrate
102 first surface
104 second surface
120 through hole
130 first aperture
140 second aperture
150 constriction part
200 glass substrate
202 first surface
204 second surface
215 initial through hole
220 through hole
225 first aperture
230 first aperture
235 second aperture
240 second aperture
250 constriction part

What is claimed is:

1. A manufacturing method of a glass substrate having through holes, comprising:
(i) irradiating at a through hole forming target position on a first surface of the glass substrate with a laser light; and
(ii) performing a wet etching treatment on the glass substrate,
wherein during the wet etching treatment being performed on the glass substrate, an ultrasonic vibration with a frequency of less than 40 kHz is applied to an etchant over at least a part of a wet etching period, referred to as an ultrasonic vibration application period.

2. The manufacturing method according to claim 1,
wherein the wet etching treatment starts at time 0 and ends at time t_{f}, and
wherein the application of the ultrasonic vibration is performed over at least a period from the time 0 to the time 0.5 t_{f}.

3. The manufacturing method according to claim 1,
wherein during the wet etching treatment being performed on the glass substrate, the glass substrate is subjected to the wet etching treatment at an etching speed that is less than or equal to 0.3 μm/minute.

4. The manufacturing method according to claim 1,
wherein during the ultrasonic vibration is applied to the etchant, an oscillatory motion is applied to the glass substrate.

5. The manufacturing method according to claim 1,
wherein the laser light is a pulsed laser with a pulse width of 100 nsec or less.

6. The manufacturing method according to claim 1,
wherein during the through hole forming target position being irradiated with the laser light, an initial through hole having a first aperture is formed at the through hole forming target position, and
wherein after performing the wet etching treatment on the glass substrate, a through hole is formed from the initial through hole.

7. The manufacturing method according to claim 6,
wherein the through hole has a first aperture with a diameter of ϕ₁ on the first surface of the glass substrate, and
wherein an aspect ratio of a thickness of the glass substrate (t) to the diameter (ϕ₁), t/ϕ₁, is 25 or less.

8. The manufacturing method according to claim 7,
wherein the diameter ϕ₁ of the first aperture of the through hole is 20 μm or less.

9. The manufacturing method according to claim 1,
wherein during the through hole forming target position being irradiated with the laser light, a reforming part is formed at the through hole forming target position, and
wherein after performing the wet etching treatment on the glass substrate, a through hole having a first aperture is formed in the reforming part.

10. A glass substrate comprising:
a first surface;
a second surface; and
a through hole that penetrates from the first surface to the second surface,
wherein the through hole has a first aperture with a first diameter ϕ₁ on the first surface and a second aperture with a second diameter ϕ₂ on the second surface, the first diameter ϕ₁ being larger than or equal to the second diameter ϕ₂,
wherein the through hole has a constriction part inside the glass substrate, the constriction part having a third diameter ϕ₃ in a cross-section orthogonal to an extending direction of the through hole, and the third diameter ϕ₃ being less than the second diameter ϕ₂,
wherein an aspect ratio of a thickness of the glass substrate (t) to the first diameter (ϕ₁), t/ϕ₁, is 25 or less, and a ratio of the third diameter (ϕ₃) to the first diameter (ϕ₁), ϕ₃/ϕ₁, is 0.50 or more, and
wherein both an arithmetic average roughness Ra of the first surface near the first aperture and an arithmetic average surface roughness Ra of the second surface near the second aperture are 0.05 μm or less.
